(19) United States
(12) Patent Application Publication
(10) Pub. No.: US 2025/0311514 A1
(43) Pub. Date: Oct. 2, 2025

(54) DISPLAY DEVICE

(71) Applicant: InnoLux Corporation, Miao-Li County (TW)

(72) Inventors: Kuan-Hung KUO, Miao-Li County (TW); Chiung-Chieh KUO, Miao-Li County (TW); Yi-Ching HUANG, Miao-Li County (TW); Chi-Hsien CHENG, Miao-Li County (TW)

(73) Assignee: InnoLux Corporation, Miao-Li County (TW)

(21) Appl. No.: 19/064,726

(22) Filed: Feb. 27, 2025

(30) Foreign Application Priority Data
Mar. 27, 2024 (CN) 202410356541.1

(51) Int. Cl. H10H 29/855; H10D 86/60; H10H 29/37; H10H 29/80; H10H 29/851

(52) U.S. Cl. CPC H10H 29/8552; H10D 86/60; H10H 29/37; H10H 29/842; H10H 29/851

(57) ABSTRACT

A display device includes a first substrate, a light emitting unit disposed on the first substrate and electrically connected to the first substrate, a light converting layer disposed on the light emitting unit, a color filter layer disposed on the light converting layer, a microlens layer disposed on the color filter layer, and a second substrate disposed on the microlens layer. The microlens layer includes a plurality of microlens units, and in a normal direction of the display device, the plurality of microlens units overlap the color filter layer.

### BACKGROUND OF THE DISCLOSURE

### 1. Field of the Disclosure

The present disclosure relates to a display device, and more particularly to a display device including microlens.

### 2. Description of the Prior Art

Current display devices may include microlens structures to improve the light emitting effect of the display devices. However, the material of the microlens will be limited by the difference between the manufacturing processes of the display device and the microlens or the requirements for the refractive index or thickness of the microlens. In addition, the appearance of the formed microlens may be poor, thereby affecting the reliability of the microlens. Therefore, to improve the above problems is still an important issue in the present field.

### SUMMARY OF THE DISCLOSURE

The present disclosure aims at providing a display device including microlens.

In some embodiments, a display device is provided by the present disclosure. The display device includes a first substrate, a light emitting unit disposed on the first substrate and electrically connected to the first substrate, a light converting layer disposed on the light emitting unit, a color filter layer disposed on the light converting layer, a microlens layer disposed on the color filter layer, and a second substrate disposed on the microlens layer. The microlens layer includes a plurality of microlens units, and in a normal direction of the display device, the plurality of microlens units overlap the color filter layer.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 schematically illustrates a manufacturing process of a display device of the present disclosure.

FIG. 2 schematically illustrates a manufacturing process of a capturing layer of the present disclosure.

FIG. 3 schematically illustrates a cross-sectional view of a display device according to a first embodiment of the present embodiment.

FIG. 4 schematically illustrates a cross-sectional view of a display device according to a second embodiment of the present embodiment.

FIG. 5 schematically illustrates a cross-sectional view of a display device according to a third embodiment of the present embodiment.

FIG. 6 schematically illustrates a manufacturing process of microlens units according to an embodiment of the present disclosure.

FIG. 7 schematically illustrates a manufacturing process of microlens units according to an embodiment of the present disclosure.

FIG. 8 schematically illustrates a manufacturing process of microlens units according to an embodiment of the present disclosure.

FIG. 9 schematically illustrates a manufacturing process of microlens units according to an embodiment of the present disclosure.

FIG. 10 schematically illustrates a manufacturing process of microlens units according to an embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the device, and certain elements in various drawings may not be drawn to scale. In addition, the number and dimension of each element shown in drawings are only illustrative and are not intended to limit the scope of the present disclosure.

Certain terms are used throughout the description and following claims to refer to particular elements. As one skilled in the art will understand, electronic equipment manufacturers may refer to an element by different names. This document does not intend to distinguish between elements that differ in name but not function.

In the following description and in the claims, the terms “include”, “comprise” and “have” are used in an open-ended fashion, and thus should be interpreted to mean “include, but not limited to . . . ”.

It will be understood that when an element or layer is referred to as being “disposed on” or “connected to” another element or layer, it can be directly on or directly connected to the other element or layer, or intervening elements or layers may be presented (indirectly). In contrast, when an element is referred to as being “directly on” or “directly connected to” another element or layer, there are no intervening elements or layers presented. When an element or a layer is referred to as being “electrically connected” to another element or layer, it can be a direct electrical connection or an indirect electrical connection. The electrical connection or coupling described in the present disclosure may refer to a direct connection or an indirect connection. In the case of a direct connection, the ends of the elements on two circuits are directly connected or connected to each other by a conductor segment. In the case of an indirect connection, switches, diodes, capacitors, inductors, resistors, other suitable elements or combinations of the above elements may be included between the ends of the elements on two circuits, but not limited thereto.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

According to the present disclosure, the thickness, length and width may be measured through optical microscope, and the thickness or width may be measured through the cross-sectional view in the electron microscope, but not limited thereto.

In addition, any two values or directions used for comparison may have certain errors. In addition, the terms “equal to”, “equal”, “the same”, “approximately” or “substantially” are generally interpreted as being within ±20%, ±10%, ±5%, ±3%, ±2%, ±1%, or ±0.5% of the given value.

In addition, the terms “the given range is from a first value to a second value” or “the given range is located between a first value and a second value” represents that the given range includes the first value, the second value and other values there between.

If a first direction is said to be perpendicular to a second direction, the included angle between the first direction and the second direction may be located between 80 to 100 degrees. If a first direction is said to be parallel to a second direction, the included angle between the first direction and the second direction may be located between 0 to 10 degrees.

Unless it is additionally defined, all terms (including technical and scientific terms) used herein have the same meaning as commonly understood by those ordinary skilled in the art. It can be understood that these terms that are defined in commonly used dictionaries should be interpreted as having meanings consistent with the relevant art and the background or content of the present disclosure, and should not be interpreted in an idealized or overly formal manner, unless it is specifically defined in the embodiments of the present disclosure.

It should be noted that the technical features in different embodiments described in the following can be replaced, recombined, or mixed with one another to constitute another embodiment without departing from the spirit of the present disclosure.

The electronic device of the present disclosure may include a display device, a sensing device, a back-light device, an antenna device, a tiled device or other suitable electronic devices, but not limited thereto. The electronic device of the present disclosure may be a foldable electronic device, a flexible electronic device or a stretchable electronic device. The display device may include a non-self-emissive display device or a self-emissive display device. The non-self-emissive display device for example includes a liquid crystal display device, but not limited thereto. The self-emissive display device for example includes a light emitting diode display device, but not limited thereto. The display device may for example be applied to laptops, common displays, tiled displays, vehicle displays, touch displays, televisions, monitors, smart phones, tablets, light source modules, lighting devices or electronic devices applied to the products mentioned above, but not limited thereto. The sensing device may include a biosensor, a touch sensor, a fingerprint sensor, other suitable sensors or combinations of the above-mentioned sensors. The antenna device may for example include a liquid crystal antenna device, but not limited thereto. The tiled device may for example include a tiled display device or a tiled antenna device, but not limited thereto. The outline of the electronic device may be a rectangle, a circle, a polygon, a shape with curved edge or other suitable shapes. The electronic device may include electronic units, wherein the electronic units may include passive elements or active elements, such as capacitor, resistor, inductor, diode, transistor, sensors, and the like. The diode may include a light emitting diode or a photo diode. The light emitting diode may for example include an organic light emitting diode (OLED) or an inorganic light emitting diode. The inorganic light emitting diode may for example include a mini light emitting diode (mini LED), a micro light emitting diode (micro LED) or a quantum dot light emitting diode (QLED), but not limited thereto. The electronic device may include peripheral systems such as driving systems, controlling systems, light source systems to support display devices, antenna devices, wearable devices (such as augmented reality devices or virtual reality devices), vehicle devices (such as windshield of car) or tiled devices. The display device is taken as an example of the electronic device for describing the contents of the present disclosure in the following, but the present disclosure is not limited thereto. The electronic device of the present disclosure may be combinations of the above-mentioned devices, such as the combination of display device and other devices, but not limited thereto.

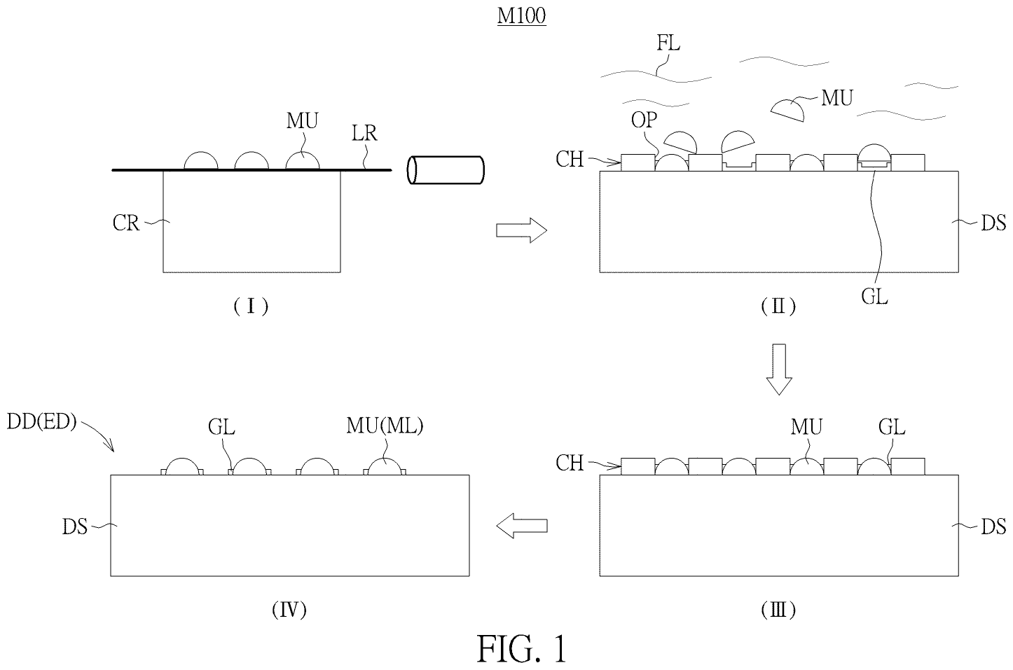

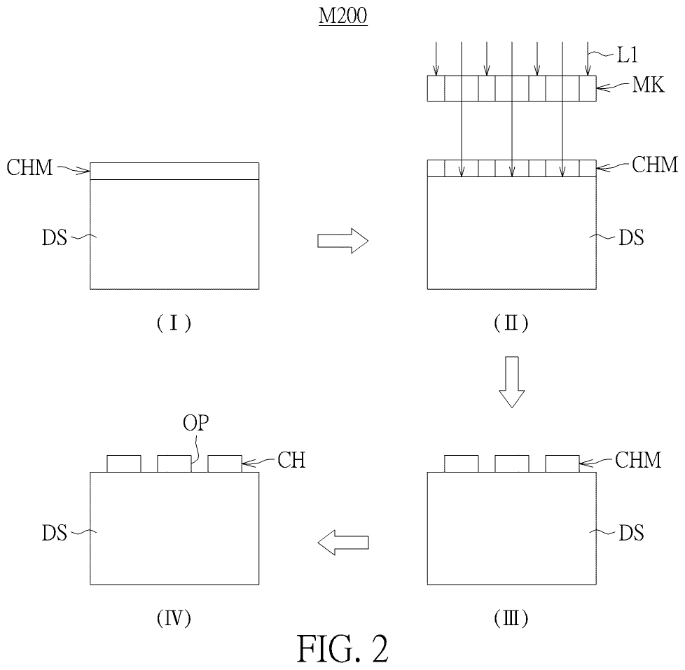

Referring to FIG. 1 and FIG. 2, FIG. 1 schematically illustrates a manufacturing process of a display device of the present disclosure, and FIG. 2 schematically illustrates a manufacturing process of a capturing layer of the present disclosure. According to the present disclosure, the electronic device ED may include a display device DD, wherein the display device DD includes a display structure DS and a microlens layer ML disposed on the display structure DS, but not limited thereto. In other embodiments, the electronic device ED may further include other suitable devices, or the electronic device ED may be combinations of the display device DD and other devices. The microlens layer ML includes a plurality of microlens units MU, wherein the plurality of microlens units MU may be arranged on the display structure DS. The display structure DS may include any device that can display images or pictures. For example, the display structure DS may include non-self-emissive display elements or self-emissive display elements. The non-self-emissive display element may for example include a liquid crystal layer, but not limited thereto. The self-emissive display element may for example include a light emitting diode, but not limited thereto. The light emitting diode may include an organic light emitting diode (OLED), a quantum dot light emitting diode (OLED or QDLED), an inorganic light emitting diode, other suitable light emitting elements or combinations of the above-mentioned elements. The inorganic light emitting diode may for example include a mini light emitting diode (mini LED) or a micro light emitting diode (micro LED), but not limited thereto. It should be noted that FIG. 1 just exemplarily shows the display structure DS as a frame, and the detail of the structure of the display structure DS may refer to the description in the following.

According to the present disclosure, the microlens layer ML (or the microlens units MU) disposed on the display structure DS may be transferred to the display structure DS through a fluid transfer process, thereby forming the display device DD. Specifically, the manufacturing method M100 of the display device DD may include following steps:
S101: forming a plurality of microlens units on a carrier;
S102: providing a display structure, and forming a capturing layer on the display structure;
S103: detaching the microlens units from a surface of the carrier, and disposing the microlens units in openings of the capturing layer through a fluid transfer process; and
S104: removing the capturing layer.

Each step of the manufacturing method M100 of the display device DD will be detailed in the following.

As shown in FIG. 1, the manufacturing method M100 of the display device DD may include the step S101: forming a plurality of microlens units MU on a carrier CR. In detail, as shown in the process (I) of FIG. 1, a carrier CR may be provided at first, and a plurality of microlens units MU are formed on a surface of the carrier CR. The carrier CR may include any suitable material that can provide supporting function during the manufacturing process of the microlens units MU and has adhesiveness with the microlens units MU. The microlens units MU may be formed on the carrier CR through any suitable method, which will be detailed in the following.

The manufacturing method M100 further includes the step S102: providing a display structure DS, and forming a capturing layer CH on the display structure DS. Specifically, after the display structure DS is formed, the capturing layer CH may be disposed on the surface of the display structure DS on which the microlens units MU are predetermined to be disposed subsequently. According to the present disclosure, the capturing layer CH may be formed through a manufacturing method M200, wherein the manufacturing method M200 includes the following steps:
S201: forming a capturing material layer on the display structure;
S202: patterning the capturing material layer; and
S203: curing the patterned capturing material layer to form the capturing layer.

Specifically, as shown in the process (I) of FIG. 2, the manufacturing method M200 of the capturing layer CH may include the step S201: forming a capturing material layer CHM on the display structure DS. The capturing material layer CHM is the layer including the material of the capturing layer CH. Specifically, the capturing material layer CHM may be entirely (or comprehensively) disposed on the surface of the display structure DS, but not limited thereto. The capturing material layer CHM may be disposed on the surface of the display structure DS through coating or other suitable processes.

After the capturing material layer CHM is formed on the display structure DS, the step S202 may be performed to pattern the capturing material layer CHM. In the present embodiment, the capturing material layer CHM may be patterned through a photolithography process. In other words, the capturing material layer CHM of the present embodiment may include any suitable photoresist material. In detail, as shown in the process (II) of FIG. 2, after the capturing material layer CHM is formed, a photomask MK may be disposed above the capturing material layer CHM, and an exposure process may be performed on the capturing material layer CHM. That is, the pattern of the photomask MK may be transferred to the capturing material layer CHM by irradiating light (that is, the light L1). After that, as shown in the process (III) of FIG. 2, after the exposure process, a development process may be performed on the capturing material layer CHM, thereby patterning the capturing material layer CHM. That is, a portion of the capturing material layer CHM is removed. In the present embodiment, after the capturing material layer CHM is patterned, the step S203 may be performed to cure the patterned capturing material layer CHM to form the capturing layer CH. In detail, as shown in the process (IV) of FIG. 2, after the development process, a curing process (for example, baked through an oven, but not limited thereto) may be performed on the patterned capturing material layer CHM to form the capturing layer CH. It should be noted that in the process (II) of FIG. 2, the capturing material layer CHM may include a negative photoresist, and after the exposure process, the portion of the capturing material layer CHM not irradiated by the light L1 may be removed in the development process, but not limited thereto. In some embodiments, the capturing material layer CHM may include a positive photoresist. After the capturing layer CH is formed, a plurality of openings OP may be included in the capturing layer CH, wherein the openings OP may define the disposition position of the microlens units MU disposed subsequently. Specifically, the microlens units MU may enter the openings OP of the capturing layer CH in a subsequent process, thereby being disposed on the display structure DS. In other words, the pattern of the photomask MK or the capturing layer CH may be determined based on the predetermined disposition position of the microlens units MU on the display structure DS. In addition, the size of the opening OP may be determined according to the size of the microlens unit MU to be disposed, such that the microlens unit MU may enter the opening OP. It should be noted that the patterning process of the capturing material layer CHM mentioned above is exemplary, and the present disclosure is not limited thereto. The capturing material layer CHM may be patterned through any suitable patterning process to form the capturing layer CH.

It should be noted that the step S101 (forming the microlens units MU on the carrier CR) and the step S102 (providing the display structure DS, and disposing the capturing layer CH on the display structure DS) may be performed simultaneously or performed in any suitable order, it is not limited in the present disclosure.

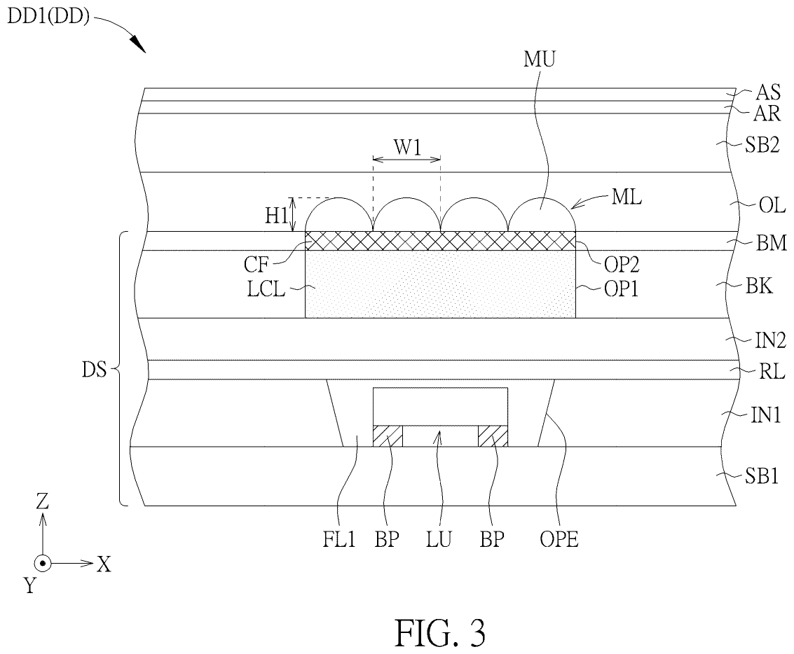

Referring to FIG. 1 again, after the step S101 and the step S102 are finished, the manufacturing method M100 of the display device DD may include the step S103: detaching the microlens units MU from a surface of the carrier CR, and disposing the microlens units MU in openings OP of the capturing layer CH through a fluid transfer process. Specifically, the microlens units MU may be detached from the surface of the carrier CR through any suitable method at first, and then the microlens units MU may be transferred to the surface of the display structure DS through any suitable fluid and disposed in the openings OP of the capturing layer CH. For example, in the present embodiment, as shown in the process (I) of FIG. 1, the microlens units MU may be detached from the surface of the carrier CR by irradiating laser LR. After that, as shown in the process (II) of FIG. 1, the microlens units MU detached from the carrier CR may be transferred from the carrier CR to the display structure DS through the fluid FL, wherein the microlens units MU may enter the openings OP of the capturing layer CH, thereby being disposed on the display structure DS. An opening OP may be used for accommodating a microlens unit MU, but not limited thereto. As shown in the process (III) of FIG. 1, after the transferring process of the microlens units MU is finished, a microlens unit MU may be disposed in each opening OP of the capturing layer CH, but not limited thereto. In some embodiments, in order to achieve the high-density arrangement of the microlens units MU shown in FIG. 3, the microlens units MU that has been attached to the display structure DS through the first transferring process mentioned above may be used as the capturing layer CH, and then one or more times of the transferring process may be performed until the disposition density of the microlens units MU meets the demand of the design.

The microlens units MU may be fixed in the openings OP of the capturing layer CH through any suitable method. For example, in the present embodiment, a glue layer GL may be disposed in the openings OP of the capturing layer CH before the microlens units MU are transferred. Therefore, when the microlens units MU enter the openings OP, the microlens units MU may be fixed in the openings OP through the glue layer GL. In another embodiment, after the microlens units MU are transferred to the openings OP, a filling layer (not shown in FIG. 1) may be filled into the openings OP, thereby fixing the microlens units MU in the openings OP. The fixing method of the microlens units MU of the present disclosure is not limited to the methods mentioned above.

After the microlens units MU are transferred to the display structure DS, the step S104 may be performed to remove the capturing layer CH. Specifically, the capturing layer CH disposed on the display structure DS may be removed through any suitable process (such as etching, but not limited thereto), and the microlens units MU disposed on the display structure DS are remained, as shown in the process (IV) of FIG. 1. After the capturing layer CH is removed, the display device DD may be formed. In addition, after the capturing layer CH is removed, the glue layer GL (or the filling layer) may not be removed, but not limited thereto. It should be noted that the manufacturing method M100 of the display device DD may further include other steps, and is not limited to the above-mentioned steps.

In short, in the manufacturing method of the display device DD of the present disclosure, the display structure DS and the microlens units MU may be formed separately, and then the microlens units MU are transferred to the display structure DS through a mass transfer process. Since the manufacturing process of the display structure DS and the manufacturing process of the microlens units MU are independent, the influence of the manufacturing process of the display structure DS on the manufacturing process of the microlens units MU may be reduced. That is, the possibility of increasing the manufacturing difficulty of the display device DD due to differences in the manufacturing conditions (such as temperature) of the display structure DS and the microlens units MU may be reduced. Therefore, the material choice of the microlens units MU may increase, and/or the demand of the manufacturing process of the microlens units MU may be reduced through the process design of the present disclosure. In such condition, the diversity of material choice of the microlens units MU may increase, thereby achieving the effect of forming the microlens units MU with specific refractive index or specific thickness according to demands of the product. In addition, the reliability of the microlens units MU formed through the manufacturing method of the present disclosure may be improved. For example, the possibility of appearance defects (such as missing corners) of the microlens unit MU may be reduced.

The structure of the display structure DS of the present disclosure will be detailed in the following. Specifically, several embodiments of the display device DD including the display structure DS of the present disclosure are described in the following. It should be noted that the manufacturing method M100 of the display device DD mentioned above may be applied to the display devices in the embodiments of the present disclosure.

Referring to FIG. 3, FIG. 3 schematically illustrates a cross-sectional view of a display device according to a first embodiment of the present embodiment. According to the present embodiment, the display device DD1 may include a first substrate SB1, a light emitting unit LU disposed on the first substrate SB1, a light converting layer LCL disposed on the light emitting unit LU, a color filter layer CF disposed on the light converting layer LCL, a microlens layer ML disposed on the color filter layer CF and a second substrate SB2 disposed on the microlens layer ML, but not limited thereto.

The first substrate SB1 of the present embodiment may include a driving substrate, such as a thin film transistor (TFT) substrate, a printed circuit board (PCB), a flexible printed circuit board or combinations thereof, such that the first substrate SB1 may drive the light emitting unit LU disposed thereon or other electronic units in the display device DD1. Specifically, the first substrate SB1 may include a base (not shown) and a circuit layer (not shown) disposed on the base. The base may be used for supporting the elements and the layers disposed thereon. The base may include a flexible material, a rigid material or combinations thereof. The flexible material may for example include polyimide (PI), polycarbonate (PC), polyethylene terephthalate (PET), other suitable materials or combinations of the above-mentioned materials. The rigid material for example includes glass, quartz, sapphire, ceramic, other suitable materials or combinations of the above-mentioned materials. The circuit layer may include various kinds of wires, circuits or electronic units that can be applied to the display device DD1. The electronic unit may include any suitable active element and/or passive element. The circuit layer may include a driving unit, wherein the driving unit may include a thin film transistor element, but not limited thereto. The light emitting unit LU disposed on the first substrate SB1 may be electrically connected to the first substrate SB1. Specifically, the light emitting unit LU may be electrically connected to the driving unit (or the thin film transistor element) in the first substrate SB1 through the bonding pad BP, such that the light emitting unit LU may be driven by the driving unit. The second substrate SB2 may serve as the opposite substrate of the first substrate SB1. The material of the second substrate SB2 may refer to the material of the base of the first substrate SB1 mentioned above, but not limited thereto.

The light emitting unit LU of the present embodiment may include a light emitting diode, such as a mini light emitting diode (mini LED), a micro light emitting diode (micro LED) or an organic light emitting diode (OLED), but not limited thereto. Specifically, the display device DD1 may include an insulating layer IN1 disposed on the first substrate SB1, wherein the insulating layer IN1 may include an opening OPE, and the light emitting unit LU may be disposed in the opening OPE. The opening OPE may expose at least a portion of the circuit layer of the first substrate SB1, such that the light emitting unit LU may be electrically connected to the driving unit. In the present embodiment, the insulating layer IN1 may serve as the pixel defining layer (PDL). The display device DD1 may further include a filling layer FL1 disposed in the opening OPE of the insulating layer IN1. The filling layer FL1 may cover the light emitting unit LU to provide protection. The filling layer FL1 may include any suitable transparent filling material, such as acrylic, silicone, epoxy resin, and the like, but not limited thereto. The insulating layer IN1 may include any suitable insulating material, such as white organic materials or black organic materials, but not limited thereto.

The light converting layer LCL may include any suitable material that can adjust the wavelength or color of the light passing through the light converting layer LCL, such as quantum dots, fluorescent, phosphorescent, other suitable materials or combinations of the above-mentioned materials, but not limited thereto. The light converting layer LCL of the present embodiment may include quantum dot, but not limited thereto. The light converting layer LCL may be disposed corresponding to the light emitting unit LU. Specifically, in a normal direction of the display device DD1 (that is, the normal direction Z of the bottom surface of the first substrate SB1), the light converting layer LCL may overlap the light emitting unit LU, such that the wavelength or color of the light emitted from the light emitting unit LU may be converted through the light converting layer LCL. In detail, the display device DD1 may further include an insulating layer IN2 disposed on the light emitting unit LU and a bank structure BK disposed on the insulating layer IN2, wherein the bank structure BK may include an opening OP1, and the light converting layer LCL may be disposed in the opening OP1 of the bank structure BK. In the normal direction of the display device DD1, the opening OP1 may overlap the opening OPE. It should be noted that although FIG. 3 just shows a light emitting unit LU and a light converting layer LCL corresponding to the light emitting unit LU, the display device DD1 of the present disclosure may include a plurality of light emitting units LU and the light converting layers LCL respectively corresponding to the light emitting units LU. In some embodiments, the light converting layers LCL may be divided into several groups, and the lights may have different wavelengths or colors after being converted by different groups of light converting layers LCL. In some embodiments, the light converting layers LCL may convert the lights into the lights having the same wavelength or color. The insulating layer IN2 may include any suitable insulating material, such as the material with high transmittance and/or adhesiveness.

The color filter layer CF may correspond to the light converting layer LCL and directly be disposed on the light converting layer LCL, but not limited thereto. Specifically, in the normal direction of the display device DD1, the color filter layer CF may overlap the light converting layer LCL. In detail, the display device DD1 may further include a black matrix layer BM disposed on the bank structure BK, wherein the black matrix layer BM includes an opening OP2, and the color filter layer CF may be disposed in the opening OP2. In the normal direction of the display device DD1, the opening OP2 may overlap the opening OP1 (or the opening OPE). The light emitted from the light emitting unit LU may pass through the color filter layer CF corresponding to a light converting layer LCL after passing through the light converting layer LCL. Therefore, the quality of output light of the display device DD1 may be improved.

According to the present embodiment, the microlens layer ML may directly be disposed on the color filter layer CF. The microlens layer ML may correspond to the color filter layer CF. The material of the microlens layer ML may include acrylic material, but not limited thereto. Specifically, in the normal direction of the display device DD1, the microlens layer ML may overlap the color filter layer CF. In other words, the microlens layer ML may also correspond to the light converting layer LCL and/or the light emitting unit LU. The microlens layer ML (or the microlens units MU) may not be disposed corresponding to the black matrix layer BM and/or the bank structure BK, that is, the microlens layer ML may not be disposed on the black matrix layer BM and/or the bank structure BK. In other words, when the capturing layer CH is formed, the openings OP of the capturing layer CH may not overlap the black matrix layer BM and/or the bank structure BK. In the present embodiment, “the microlens layer ML overlaps the color filter layer CF” mentioned above may represent that the plurality of microlens units MU of the microlens layer ML overlap the color filter layer CF, but not limited thereto. Specifically, in the normal direction of the display device DD1, a color filter layer CF may overlap a plurality of microlens units MU of the microlens layer ML. For example, FIG. 3 shows a structure in which a color filter layer CF overlaps four microlens units MU, but not limited thereto. In some embodiments, a color filter layer CF may overlap a microlens unit MU of the microlens layer ML. Although it is not shown in FIG. 3, the display device DD1 may include a plurality of color filter layers CF, and the plurality of color filter layers CF may respectively overlap one or more microlens units MU. It should be noted that the numbers of the microlens units MU corresponding to each of the color filter layers CF may be the same or different, and the colors of the color filter layers CF may be the same or different, it is not limited in the present disclosure.

According to the present disclosure, the refractive index of the microlens unit MU may be greater than or equal to 1.7, but not limited thereto. In some embodiments, the refractive index of the microlens unit MU may be greater than or equal to 1.8. In some embodiments, the refractive index of the microlens unit MU may be greater than or equal to 1.9. In addition, the microlens unit MU may have a thickness H1, wherein the thickness H1 may range from 3 micrometers (μm) to 20 μm (that is, 3 μm≤H1≤20 μm), but not limited thereto. In some embodiments, the thickness H1 may range from 5 μm to 15 μm (that is, 5 μm≤H1≤15 μm). The thickness H1 may be defined as the maximum thickness of the microlens unit MU in the normal direction Z of the display device DD1. In a cross-sectional view of the display device DD1 (for example, FIG. 3), the microlens unit MU may have a width W1, wherein the width W1 may range from 5 μm to 70 μm (that is, 5 μm≤W1≤70 μm), but not limited thereto. The width W1 may be defined as the maximum width of the microlens unit MU in a direction X perpendicular to the normal direction Z of the display device DD1 in the cross-sectional view of the display device DD1. In some embodiments, the width W1 may range from 10 μm to 40 μm (that is, 10 μm≤W1≤40 μm). Through the above demands of the refractive index, thickness H1 and width W1 of the microlens unit MU, the performance of the microlens unit MU may be improved.

In addition, in the present embodiment, the light emitting unit LU, the light converting layer LCL and the color filter layer CF may form a pixel (or a sub-pixel), wherein in a top view of the display device DD1 (or on a plane parallel to the plane XY, wherein the direction X and the direction Y are perpendicular to each other, and the plane XY formed of the direction X and the direction Y is perpendicular to the normal direction Z), the pixel may have a size, wherein the width of the pixel may for example be between 50 μm and 80 μm, and the length of the pixel may for example be between 100 μm and 250 μm. The size of the pixel mentioned above may be defined as the size of the light emitting unit LU, the light converting layer LCL or the color filter layer CF which has the greatest projection area in the top view of the display device DD1. For example, according to the structure shown in FIG. 3, the region of the pixel may be the region enclosed by the outer edge of the light converting layer LCL (or the color filter layer CF) in the top view of the display device DD1, and the size of the pixel may be the size of the region, but not limited thereto. That is, the region of the pixel may have a first side and a second side adjacent to the first side, wherein the length of the first side may range from 50 μm to 80 μm, and the length of the second side may range from 100 μm to 250 μm. Through the above-mentioned designs of the pixel size and the width W1 of the microlens unit MU, a color filter layer CF may overlap a plurality of microlens units MU. Specifically, the size (width W1) of the microlens unit MU may be designed according to the number of microlens units MU corresponding to a color filter layer CF.

In the present disclosure, through the manufacturing method M100 of the display device DD mentioned above, the material choice or manufacturing process of the microlens unit MU may not be affected by the manufacturing process of the display structure DS. In such condition, the diversity of material choice of the microlens unit MU of the present disclosure may increase, or the process conditions of the microlens unit MU may be relaxed. Therefore, compared with the manufacturing process of current display device, it is easier to form the microlens unit MU that meets the above demands of the refractive index, the thickness H1, and the width W1.

In some embodiments, the display device DD1 may further include an optical layer OL, wherein the optical layer OL may be disposed between the microlens layer ML and the second substrate SB2. Specifically, the optical layer OL may directly be disposed on the microlens layer ML, that is, the optical layer OL may contact the microlens units MU. The optical layer OL may include a low refractive index material. The “low refractive index material” described herein may indicate the material with a refractive index of less than 1.5, such as acrylic, polyimide (PI), siloxane, and the like, but not limited thereto. In other words, the refractive index of the optical layer OL may be less than the refractive index (for example, 1.7) of the microlens units MU. By disposing the optical layer OL on the microlens layer ML, the light emitting effect of the display device DD1 may be improved. It should be noted that when both the microlens layer ML and the optical layer OL are made of acrylic materials, the refractive index of the acrylic material included in the microlens layer ML may be greater than the refractive index of the acrylic material included in the optical layer OL.

In some embodiments, the display device DD1 may further include an optical adjusting layer RL, wherein the optical adjusting layer RL may be disposed between the light emitting unit LU and the light converting layer LCL, but not limited thereto. Through the disposition of the optical adjusting layer RL, the path of the light emitted from the light emitting unit LU may be adjusted, thereby increasing the amount of output light of the display device DD1 or improving the light converting efficiency of the light converting layer LCL. In some embodiments of the present disclosure, the optical adjusting layer RL may be a bragg reflector having a multi-layer structure, wherein the optical interference phenomenon may be caused by the difference in refractive indexes of the layers of the bragg reflector, thereby improving the light emitting efficiency, but not limited thereto. In some embodiments, the optical adjusting layer RL may have a prism structure to provide focusing effect of light.

In some embodiments, the display device DD1 may further include an anti-reflection layer AR, wherein the anti-reflection layer AR may be disposed on the second substrate SB2. In some embodiments, the anti-reflection layer AR may be formed by using coating technology to dispose a plurality of layers with different refractive indexes on the top surface of the second substrate SB2. More specifically, the anti-reflection layer AR may include a structure formed by stacking multiple high refractive index sub-layers (not shown) and multiple low refractive index sub-layers (not shown) alternately. In some embodiments, the display device DD1 may further include an antifouling layer AS, wherein the antifouling layer AS may be disposed on the anti-reflection layer AR. The antifouling layer AS may for example be a coating of a material with oil-proof or water-proof properties (such as silicon dioxide or fluorine-containing materials), but not limited thereto. In other words, the anti-reflection layer AR may be disposed between the antifouling layer AS and the second substrate SB2.

Referring to FIG. 1 and FIG. 3, in the present embodiment, the portion of the display device DD1 located below the microlens layer ML may be regarded as the above-mentioned display structure DS. In other words, the display structure DS of the present embodiment may include the first substrate SB1, the color filter layer CF, and the layers and elements located there between. In such condition, after the display structure DS is formed, the capturing layer CH may be formed on the surface of the color filter layer CF and the surface of the black matrix layer BM (that is, the surface at a side of the color filter layer CF and the surface at a side of the black matrix layer BM away from the first substrate SB1), and then the microlens units MU may be disposed on the color filter layer CF through the fluid transfer process. After that, the capturing layer CH may be removed, and the layers such as the optical layer OL, the second substrate SB2, the anti-reflection layer AR and/or the antifouling layer AS may be formed on the microlens units MU, thereby forming the display device DD1.

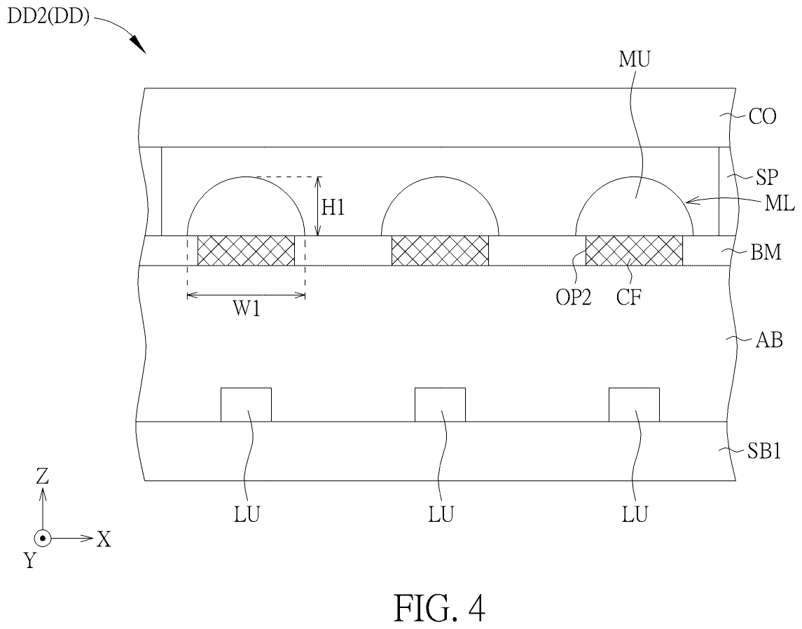

Referring to FIG. 4, FIG. 4 schematically illustrates a cross-sectional view of a display device according to a second embodiment of the present embodiment. According to the present embodiment, the display device DD2 may include the first substrate SB1, the light emitting units LU disposed on the first substrate SB1, the color filter layers CF disposed on the light emitting units LU and the microlens layer ML disposed on the color filter layers CF. The structural features of the first substrate SB1 and the light emitting unit LU may refer to the contents above, and will not be redundantly described. In the present embodiment, the display device DD2 may further include a low refractive index layer AB, wherein the low refractive index layer AB may be disposed on the first substrate SB1 and cover the light emitting units LU, and the refractive index of the low refractive index layer AB is less than the refractive index of the microlens units MU. For example, the refractive index of the low refractive index layer AB may range from 1 to 1.5 (that is, 1≤refractive index≤1.5). In some embodiments, the low refractive index layer AB may be an air layer. The color filter layers CF may be disposed on the low refractive index layer AB. In the normal direction of the display device DD2, the color filter layers CF may overlap the light emitting units LU. In detail, the display device DD2 may further include the black matrix layer BM, wherein the black matrix layer BM is disposed on the low refractive index layer AB and may include the openings OP2 corresponding to the light emitting units LU, and the color filter layers CF may be disposed in the openings OP2. The microlens layer ML may be disposed corresponding to the color filter layers CF. Specifically, the microlens layer ML may directly be disposed on the color filter layers CF, or the microlens units MU may contact the color filter layers CF. In the present embodiment, as shown in FIG. 4, a color filter layer CF may overlap a microlens unit MU of the microlens layer ML in the normal direction of the display device DD2, but not limited thereto. In some embodiments, a color filter layer CF may overlap a plurality of microlens units MU in the normal direction of the display device DD2. The refractive index, the width W1 and the thickness H1 of the microlens units MU of the present embodiment may refer to the contents above, and will not be redundantly described.

In some embodiments, the display device DD2 may further include spacers SP and a cover layer CO, wherein the cover layer CO may be disposed on the microlens layer ML, and the spacers SP may be disposed between the cover layer CO and the microlens layer ML. Specifically, the spacers SP may be disposed on the black matrix layer BM and support the cover layer CO. It should be noted that the disposition condition of the spacers SP shown in FIG. 4 is exemplary, and the present embodiment is not limited thereto. In some embodiments, the spacers SP may be disposed at any suitable position corresponding to the black matrix layer BM. Through the disposition of the spacers SP, there may be an air medium layer on the microlens layer ML and located between the microlens layer ML and the cover layer CO. Since the refractive index of the air medium layer is less than the refractive index of the microlens unit MU, the light emitting effect of the display device DD2 may be improved. It should be noted that the structure of the spacers SP of the present embodiment may be applied to the display device DD1 shown in FIG. 3. Specifically, based on the structure shown in FIG. 3, after the microlens layer ML is disposed, the spacers SP may be disposed at the position corresponding to the black matrix layer BM instead of the optical layer OL. After that, the layers such as the second substrate SB2, the anti-reflection layer AR, the antifouling layer AS, and the like may be formed to form the display device DD1. In addition, the optical layer OL shown in FIG. 3 may be applied to the display device DD2 of the present disclosure. Specifically, based on the structure shown in FIG. 4, after the microlens layer ML is disposed, the optical layer OL may be disposed on the microlens layer ML. After that, the cover layer CO may be disposed on the optical layer OL to form the display device DD2. The cover layer CO may include any suitable protecting material, such as glass, but not limited thereto.

Referring to FIG. 1 and FIG. 4, in the present embodiment, the portion of the display device DD2 located below the microlens layer ML may be regarded as the display structure DS mentioned above. In other words, the display structure DS of the present embodiment may include the first substrate SB1, the light emitting units LU, the low refractive index layer AB, the color filter layers CF and the black matrix layer BM, but not limited thereto. In such condition, after the display structure DS is formed, the capturing layer CH may be formed on the surfaces of the color filter layers CF and the black matrix layer BM (the surfaces at the side away from the first substrate SB1), and then the microlens unit MU may be disposed on the color filter layers CF through the fluid transfer process. After that, the capturing layer CH may be removed, and the spacers SP and the cover layer CO may be formed on the microlens units MU, thereby forming the display device DD2.

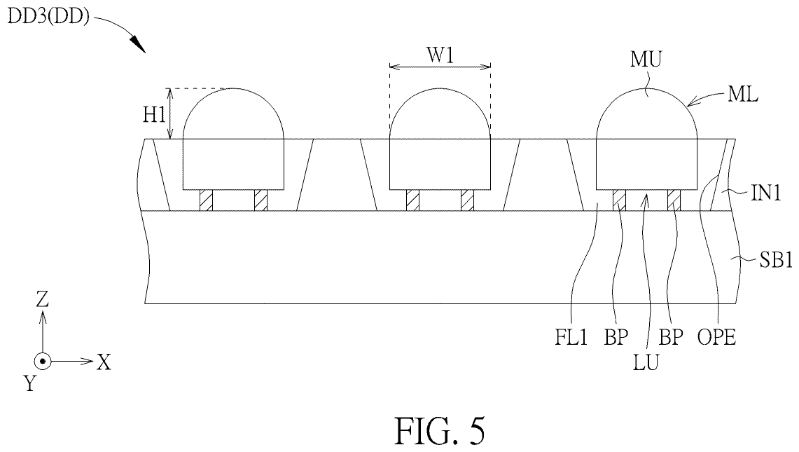

Referring to FIG. 5, FIG. 5 schematically illustrates a cross-sectional view of a display device according to a third embodiment of the present embodiment. According to the present embodiment, the display device DD3 may include the first substrate SB1, the light emitting units LU disposed on the first substrate SB1 and the microlens layer ML disposed on the light emitting units LU. Specifically, the display device DD3 may further include the insulating layer IN1 disposed on the first substrate SB1, wherein the insulating layer IN1 may include the openings OPE, and the light emitting units LU may be disposed in the openings OPE. The structural features of the first substrate SB1, the light emitting units LU and the insulating layer IN1 may refer to the contents mentioned above, and will not be redundantly described. The display device DD3 may further include a filling layer FL1 disposed in the openings OPE of the insulating layer IN1. The filling layer FL1 may be disposed to be adjacent to the light emitting unit LU (for example, in FIG. 5, the filling layer FL1 may be disposed to surround the light emitting unit LU, and a portion of the filling layer FL1 is located between two bonding pads BP), thereby providing protection to the light emitting unit LU. In the present embodiment, the microlens layer ML may be disposed corresponding to the light emitting units LU. Specifically, the microlens layer ML may directly be disposed on the light emitting units LU, or the microlens layer ML may contact the surfaces of the light emitting units LU (the surfaces of the light emitting units LU at the side away from the first substrate SB1). That is, in the normal direction of the display device DD3, the microlens units MU may overlap the light emitting units LU. In addition, in the present embodiment, a color filter layer (not shown) may overlap a microlens unit MU of the microlens layer ML in the normal direction of the display device DD3, but not limited thereto. In some embodiments, a color filter layer (not shown) may overlap a plurality of microlens units MU in the normal direction of the display device DD3. The refractive index, the width W1 and the thickness H1 of the microlens unit MU of the present embodiment may refer to the contents mentioned above, and will not be redundantly described. It should be noted that the display device DD3 may further include other suitable elements or layers, which is not limited to the structure shown in FIG. 5. In some embodiments, the display device DD3 may further include the optical layer OL shown in FIG. 3 which is disposed on the microlens layer ML. In some embodiments, the display device DD3 may further include the spacers SP shown in FIG. 4 which is disposed on the insulating layer IN1 or disposed corresponding to the insulating layer IN1.

Referring to FIG. 1 and FIG. 5, in the present embodiment, the portion of the display device DD3 located below the microlens layer ML may be regarded as the display structure DS mentioned above. In other words, the display structure DS of the present embodiment may include the layers or the elements such as the first substrate SB1, the light emitting units LU, the insulating layer IN1, the filling layer FL1, and the like, but not limited thereto. In such condition, after the display structure DS is formed, the capturing layer CH may be formed on the surfaces of the light emitting units LU and the filling layer FL1 (the surfaces at the side away from the first substrate SB1), and then the microlens units MU may be disposed on the light emitting units LU through the fluid transfer process. After that, the capturing layer CH may be removed, thereby forming the display device DD3.

It should be noted that the display devices shown in FIG. 3 to FIG. 5 are exemplary, and the present disclosure is not limited thereto. The display device of the present disclosure may include other suitable display structures.

The manufacturing methods of the microlens units MU of the present disclosure will be detailed in the following.

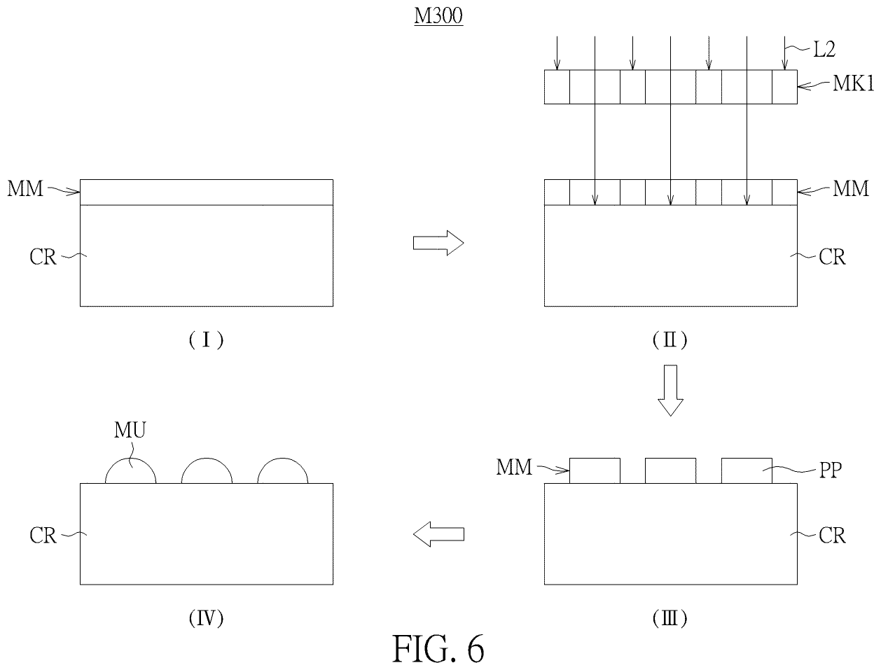

Referring to FIG. 6, FIG. 6 schematically illustrates a manufacturing process of microlens units according to an embodiment of the present disclosure. According to the present embodiment, the manufacturing method M300 of the microlens units MU may include the following steps:
S301: providing a carrier, and forming a microlens material layer on the carrier;
S302: patterning the microlens material layer; and
S303: performing a reflow process on the microlens material layer to form the microlens units.

The steps in the manufacturing method M300 of the microlens units MU will be detailed in the following.

As shown in FIG. 6, the manufacturing method M300 of the microlens units MU may include performing the step S301: providing a carrier CR, and forming a microlens material layer MM on the carrier CR at first, which is shown in the process (I) of FIG. 6. The feature of the carrier CR may refer to the contents above, and will not be redundantly described. The microlens material layer MM may be the layer including the material of the microlens units MU. Specifically, the microlens material layer MM may be entirely (or comprehensively) disposed on the surface of the carrier CR at first. The microlens material layer MM may be disposed on the surface of the carrier CR through coating or other suitable processes.

After the microlens material layer MM is disposed, the step S302 may be performed to pattern the microlens material layer MM. In the present embodiment, the microlens material layer MM may be patterned through a lithography process. In such condition, the microlens material layer MM may include any suitable photoresist material. As shown in the process (II) of FIG. 6, after the microlens material layer MM is formed, a photomask MK1 may be disposed above the microlens material layer MM, and an exposure process and a development process may be performed on the microlens material layer MM. That is, the pattern of the photomask MK1 may be transferred to the microlens material layer MM by irradiating light (that is, the light L2), thereby patterning the microlens material layer MM. As shown in the process (III) of FIG. 6, after the patterning process of the microlens material layer MM, the microlens material layer MM may be divided into a plurality of portions PP, wherein each of the portions PP may form a microlens unit MU in subsequent processes, but not limited thereto.

After the patterning process of the microlens material layer MM, the step S303 may be performed to perform a reflow process on the patterned microlens material layer MM. By performing a reflow process on the microlens material layer MM, the microlens material layer MM may be softened and flow, such that each of the portions PP may form a hemispherical structure, as shown in process (IV) of FIG. 6. Therefore, after the microlens material layer MM is cured, each of the portions PP may form a microlens unit MU having a hemispherical structure. For example, in an example, the microlens material layer MM may include acryl resin, and the above-mentioned reflow process may be performed at a temperature of 150° C. to 250° C. to form the plurality of microlens units MU on the carrier CR, but not limited thereto.

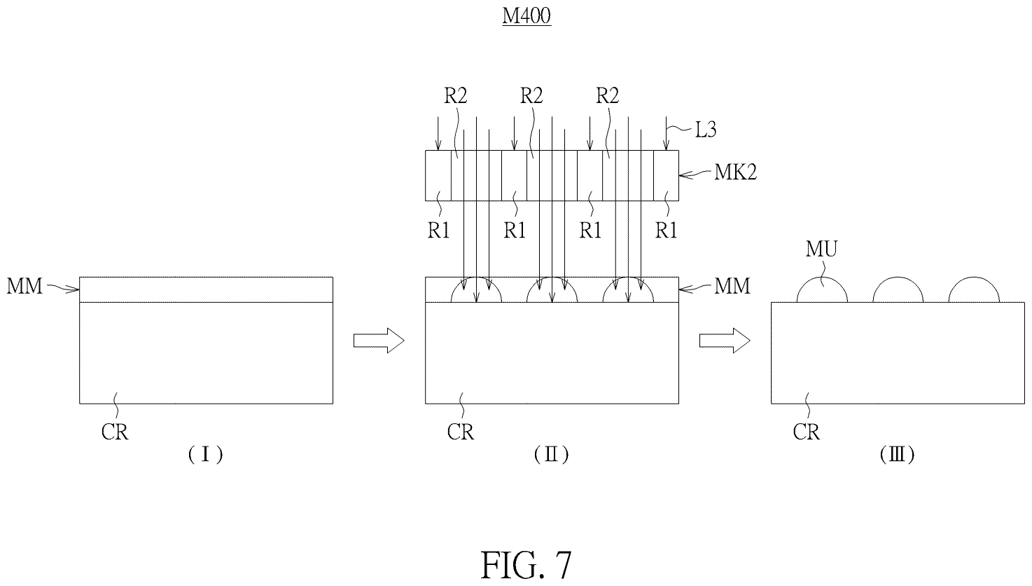

Referring to FIG. 7, FIG. 7 schematically illustrates a manufacturing process of microlens units according to an embodiment of the present disclosure. According to the present embodiment, the manufacturing method M400 of the microlens units MU may include the following steps:
S401: providing a carrier, and forming a microlens material layer on the carrier; and
S402: patterning the microlens material layer to form the microlens units.

The steps in the manufacturing method M400 of the microlens units MU will be detailed in the following.

As shown in the process (I) of FIG. 7, the manufacturing method M400 of the microlens units MU may include performing the step S401: providing a carrier CR, and forming a microlens material layer MM on the carrier CR at first. The detail of the step S401 may refer to the step S301 mentioned above, and will not be redundantly described.

After that, the step S402 may be performed to pattern the microlens material layer MM. In the present embodiment, the microlens material layer MM may be patterned through a lithography process. In detail, as shown in the process (II) of FIG. 7, after the microlens material layer MM is formed, a photomask MK2 may be disposed above the microlens material layer MM, and an exposure process may be performed on the microlens material layer MM by irradiating light (the light L3). According to the present embodiment, the photomask MK2 may be a gray scale mask. Specifically, the photomask MK2 may have different gray scales in different areas, such that the intensities of the lights passing through different areas of the photomask MK2 may be different. In such condition, after the exposure process is performed on the microlens material layer MM through the photomask MK2, different areas of the microlens material layer MM may be removed in different degrees during the development process, or the patterned microlens material layer MM may have height variation. Therefore, the microlens units MU having desired shape (such as a hemispherical shape) may be formed, as shown in the process (III) of FIG. 7. The gray scale design of the photomask MK2 may be determined according to the shape of the microlens unit MU. For example, as shown in the process (II) of FIG. 7, after the photomask MK2 is disposed above the microlens material layer MM, the photomask MK2 may include the area R2 corresponding to the predetermined disposition positions of the microlens units MU and the area R1 other than the area R2. The area R1 of the photomask MK2 may have specific gray scale, such that the portion of the microlens material layer MM corresponding to the area R1 may be completely removed after the lithography process; the area R2 of the photomask MK2 may have specific grayscale variation according to the shape of the microlens unit MU to be formed, such that the portion of the microlens material layer MM corresponding to the area R2 may be removed in different degrees at different positions after the lithography process, but not limited thereto.

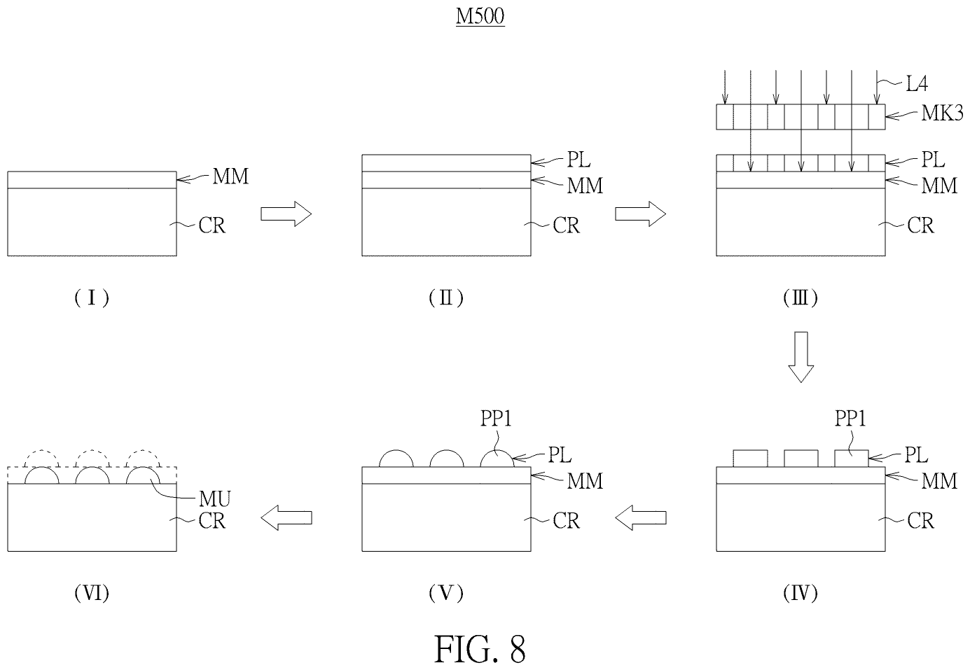

Referring to FIG. 8, FIG. 8 schematically illustrates a manufacturing process of microlens units according to an embodiment of the present disclosure. According to the present embodiment, the manufacturing method M500 of the microlens units MU may include the following steps:
S501: providing a carrier, and forming a microlens material layer on the carrier;
S502: disposing a protecting layer on the microlens material layer;
S503: patterning the protecting layer;
S504: performing a reflow process on the protecting layer; and
S505: performing an etching process on the microlens material layer and the protecting layer to form the microlens units.

The steps in the manufacturing method M500 of the microlens units MU will be detailed in the following.

As shown in the process (I) of FIG. 8, the manufacturing method M500 of the microlens units MU may include performing the step S501: providing a carrier CR, and forming a microlens material layer MM on the carrier CR at first. Specifically, the microlens material layer MM may be entirely (or comprehensively) disposed on the surface of the carrier CR (for example, through coating) at first. In the present embodiment, after the microlens material layer MM is disposed on the carrier CR, a curing process may be performed on the microlens material layer MM to cure the microlens material layer MM. The microlens material layer MM of the present embodiment may for example include any suitable photoresist material, but not limited thereto.

After that, as shown in the process (II) of FIG. 8, the manufacturing method M500 may include the step S502: disposing a protecting layer PL on the microlens material layer MM. The protecting layer PL may be entirely (or comprehensively) disposed on the microlens material layer MM and cover the microlens material layer MM. The protecting layer PL may for example be disposed on the microlens material layer MM through coating, but not limited thereto.

After the protecting layer PL is disposed, the manufacturing method M500 may include the step S503: performing a patterning process on the protecting layer PL to pattern the protecting layer PL. In the present embodiment, the protecting layer PL may be patterned through a lithography process. In such condition, the protecting layer PL may include photoresist material, but not limited thereto. In detail, as shown in the process (III) of FIG. 8, a photomask MK3 may be disposed above the protecting layer PL, and an exposure process and a development process may be performed on the protecting layer PL. That is, the pattern of the photomask MK3 may be transferred to the protecting layer PL by irradiating light (that is, the light L4), thereby patterning the protecting layer PL. After the patterning process of the protecting layer PL, the protecting layer PL may be divided into a plurality of portions PP1. In other words, an entire layer of the microlens material layer MM and a plurality of portions PP1 may be disposed on the carrier CR, as shown in the process (IV) of FIG. 8.

After the protecting layer PL is patterned, the manufacturing method M500 may include the step S504: performing a reflow process on the protecting layer PL. By performing the reflow process on the protecting layer PL, the protecting layer PL may be softened and flow, such that each of the portions PP1 may form a hemispherical structure, as shown in process (V) of FIG. 8. According to the present embodiment, after the reflow process, the shape of the portion PP1 of the protecting layer PL may be the same as or similar to the shape of the microlens unit MU to be formed.

After that, the manufacturing method M500 may include the step S505: performing an etching process on the microlens material layer MM and the protecting layer PL. In detail, after the reflow process of the protecting layer PL, an etch back process may be performed on the patterned protecting layer PL and the microlens material layer MM to remove the protecting layer PL and patterning the microlens material layer MM. According to the present embodiment, in the etch back process of the protecting layer PL and the microlens material layer MM, the protecting layer PL and the microlens material layer MM disposed on the carrier CR may be uniformly removed. Specifically, the protecting layer PL and/or the microlens material layer MM may be removed to the same or very similar extent at any position. “The protecting layer PL and/or the microlens material layer MM may be removed to the same or very similar extent” mentioned above may for example represent that the thicknesses of the removed portions of the protecting layer PL and/or the microlens material layer MM at different positions are the same or very similar. In other words, after the etch back process of the protecting layer PL and the microlens material layer MM, the thickness drop of the protecting layer PL and/or the microlens material layer MM may substantially be fixed at different positions. In such condition, by removing the protecting layer PL and/or the microlens material layer MM with certain thickness, the protecting layer PL may be removed, and the pattern of the protecting layer PL (or the pattern of the microlens unit MU to be formed) may be transferred to the microlens material layer MM located there below, as shown in the process (VI) of FIG. 8. Therefore, the microlens material layer MM may be patterned to form the microlens units MU.

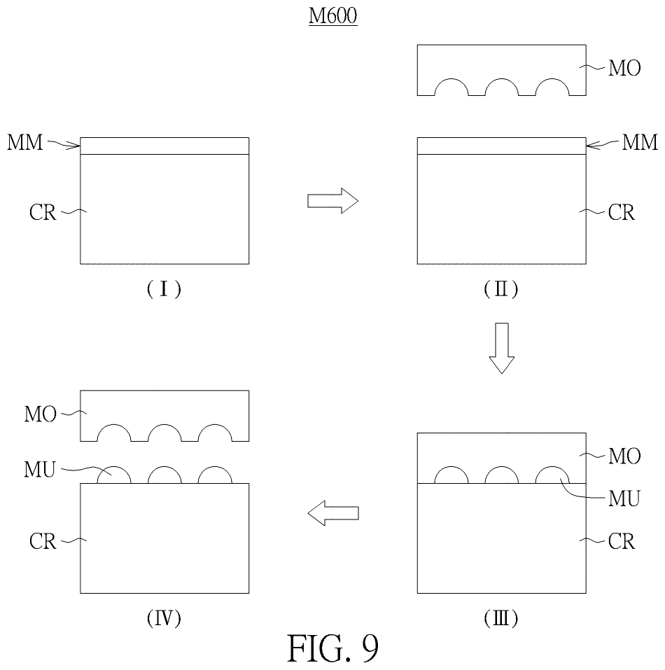

Referring to FIG. 9, FIG. 9 schematically illustrates a manufacturing process of microlens units according to an embodiment of the present disclosure. According to the present embodiment, the manufacturing method M600 of the microlens units MU may include the following steps:
S601: providing a carrier, and forming a microlens material layer on the carrier;
S602: providing a mold, and aligning the mold to the microlens material layer;
S603: performing an imprinting process on the microlens material layer through the mold to form the microlens units; and
S604: Separating the mold from the microlens material layer.

The steps in the manufacturing method M600 of the microlens units MU will be detailed in the following.

As shown in the process (I) of FIG. 9, the manufacturing method M600 of the microlens units MU may include performing the step S601: providing a carrier CR, and forming a microlens material layer MM on the carrier CR at first. The detail of the step S601 may refer to the step S301 mentioned above, and will not be redundantly described.

The manufacturing method M600 may further include the step S602: providing a mold MO. Specifically, the mold MO may be made according to the shape of the microlens unit MU to be formed. After the mold MO is formed, the mold MO may be aligned with the microlens material layer MM disposed on the carrier CR, as shown in the process (II) of FIG. 9.

After that, the manufacturing method M600 may include the step S603: performing an imprinting process on the microlens material layer MM through the mold MO. Specifically, as shown in the process (III) of FIG. 9, after the mold MO is aligned with the microlens material layer MM, the mold MO may be pressed down until it contacts the carrier CR, such that the mold MO squeezes the microlens material layer MM. Therefore, the pattern of the mold MO (or the pattern of the microlens unit MU to be formed) may be transferred to the microlens material layer MM. After that, a curing process may be performed on the microlens material layer MM to obtain the microlens units MU. In other words, the manufacturing method M600 of the microlens units MU of the present embodiment may include an imprinting process, such as a nano imprint lithography (NIL) process, but not limited thereto.

After the microlens material layer MM is cured to obtain the microlens units MU, the manufacturing method M600 may further include the step S604: separating the mold MO from the microlens units MU. Therefore, the plurality of microlens units MU may be formed on the carrier CR.

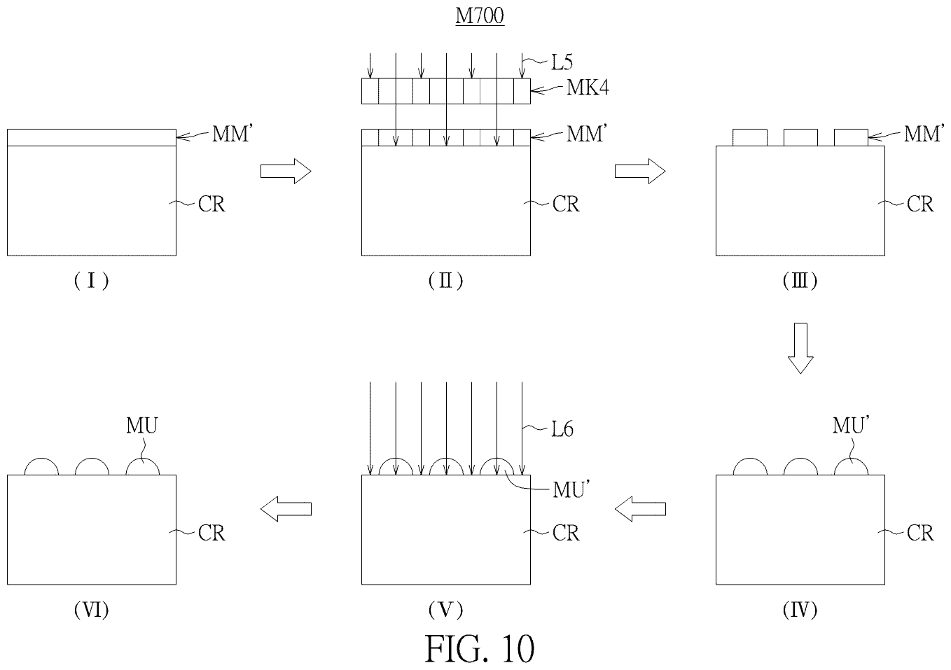

Referring to FIG. 10, FIG. 10 schematically illustrates a manufacturing process of microlens units according to an embodiment of the present disclosure. According to the present embodiment, the manufacturing method M700 of the microlens units MU may include the following steps:
S701: providing a carrier, and forming a pre-microlens material layer on the carrier;
S702: patterning the pre-microlens material layer;
S703: performing a reflow process on the pre-microlens material layer to form pre-microlens units; and
S704: performing a material modification process on the pre-microlens units to MU′.

The steps in the manufacturing method M700 of the microlens units MU will be detailed in the following.

As shown in the process (I) of FIG. 10, the manufacturing method M700 of the microlens units MU may include performing the step S701: providing a carrier CR, and forming a pre-microlens material layer MM′ on the carrier CR at first. The forming method of the pre-microlens material layer MM′ may refer to the forming method (such as the step S301) of the microlens material layer MM mentioned above, and will not be redundantly described.

After that, as shown in the process (II) and the process (III) of FIG. 10, the manufacturing method M700 may include the step S702: patterning the pre-microlens material layer MM′. In the present embodiment, the pre-microlens material layer MM′ may be patterned through a lithography process. In detail, a photomask MK4 may be disposed above the pre-microlens material layer MM′, and an exposure process and a development process may be performed on the pre-microlens material layer MM′ by irradiating light (the light L5), thereby patterning the pre-microlens material layer MM′.

After the pre-microlens material layer MM′ is patterned, the manufacturing method M700 may include the step S703: performing a reflow process on the pre-microlens material layer MM′. The pre-microlens material layer MM′ may be softened and flow through the reflow process, thereby forming pre-microlens units MU′, as shown in the process (IV) of FIG. 10. The shape of the pre-microlens units MU′ may be the same as or similar to the shape of the microlens units MU to be formed. The detail of the reflow process of the pre-microlens material layer MM′ may refer to the reflow process of the microlens material layer MM (such as the step S303) mentioned above, and will not be redundantly described.

After the pre-microlens units MU′ are formed on the carrier CR, the manufacturing method M700 may include the step S704: performing a material modification process on the pre-microlens units MU′ to transform the pre-microlens units MU′ into the microlens units MU. The material modification process of the pre-microlens units MU′ may be performed through any suitable method. For example, in the present embodiment, a specific property (such as the refractive index, but not limited thereto) of the material of the pre-microlens unit MU′ may be changed by irradiating light of a specific wavelength. In such condition, as shown in the process (V) of FIG. 10, the specific property of the material of the pre-microlens unit MU′ may be changed by irradiating the pre-microlens unit MU′ with light of the specific wavelength (that is, the light L6). In the present embodiment, the pre-microlens units MU′ may be transformed into the microlens units MU by performing a material modification process on the pre-microlens units MU′. In other words, the material of the pre-microlens unit MU′ may serve as the material of the microlens unit MU after modification. For example, in an embodiment, a material with low refractive index (for example, a refractive index less than 1.5) may be selected to form the pre-microlens material layer MM′, and the pre-microlens units MU′ may be formed through the above-mentioned processes, wherein the refractive index of the material may be changed (for example, become greater) by irradiating the material with light of a specific wavelength. After that, the material modification process may be performed on the pre-microlens units MU′, thereby forming the microlens units MU having high refractive index (for example, a refractive index of at least 1.7), which meets the demand of the refractive index of the microlens units MU mentioned above. In other words, a low refractive index material may be used to form the pre-microlens units MU′ through the above-mentioned processes at first, and then the microlens units MU with high refractive index may be obtained through the material modification process. The manufacturing method M700 of the present embodiment may improve the process flexibility of the microlens units MU.

It should be noted that the microlens units MU of the present disclosure may be formed through other suitable methods, which is not limited to the processes shown in FIG. 6 to FIG. 10. After the microlens units MU are formed through the methods mentioned above, the microlens units MU may be transferred to any display structure DS in the above-mentioned embodiments through the fluid transfer process to form the display device DD.

In summary, a display device is provided by the present disclosure, wherein the display device includes a display structure and a plurality of microlens units disposed on the display structure. The microlens units may be formed on a carrier at first, and then be transferred to the display structure through fluid transfer. Therefore, the influence of the manufacturing process of the display structure on the manufacturing process of the microlens units may be reduced. In addition, through the above-mentioned processes, one or a plurality of microlens units may directly be disposed on the light converting layers, the color filter layers or the light emitting units of the display structure. Moreover, compared with the manufacturing process of current display device, the above-mentioned manufacturing processes may more easily form the microlens units that meet the above-mentioned demands of the refractive index, the thickness and the width.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A display device, comprising:
a first substrate;
a light emitting unit disposed on the first substrate and electrically connected to the first substrate;
a light converting layer disposed on the light emitting unit;
a color filter layer disposed on the light converting layer;
a microlens layer disposed on the color filter layer, wherein the microlens layer comprises a plurality of microlens units, and in a normal direction of the display device, the plurality of microlens units overlap the color filter layer; and
a second substrate disposed on the microlens layer.

2. The display device of claim 1, further comprising an optical layer disposed between the microlens layer and the second substrate, wherein a refractive index of the optical layer is less than a refractive index of the plurality of microlens units.

3. The display device of claim 2, wherein the refractive index of the optical layer is less than 1.5.

4. The display device of claim 1, wherein the plurality of microlens units directly contact the color filter layer.

5. The display device of claim 1, wherein the first substrate comprises a thin film transistor substrate.

6. The display device of claim 1, wherein a width of one of the plurality of microlens units ranges from 5 micrometers to 70 micrometers.

7. The display device of claim 1, wherein a width of one of the plurality of microlens units ranges from 10 micrometers to 40 micrometers.

8. The display device of claim 1, wherein a refractive index of the microlens layer is greater than or equal to 1.7.

9. The display device of claim 1, wherein a refractive index of the microlens layer is greater than or equal to 1.8.

10. The display device of claim 1, wherein a refractive index of the microlens layer is greater than or equal to 1.9.

11. The display device of claim 1, wherein a thickness of the microlens layer ranges from 3 micrometers to 20 micrometers.

12. The display device of claim 1, wherein a thickness of the microlens layer ranges from 5 micrometers to 15 micrometers.

13. The display device of claim 1, further comprising a pixel defining layer disposed on the first substrate, wherein the pixel defining layer comprises an opening, and the light emitting unit is disposed in the opening.

14. The display device of claim 1, further comprising a bank structure disposed on the first substrate, wherein the bank structure comprises an opening, and the light converting layer is disposed in the opening.

15. The display device of claim 14, wherein the plurality of microlens units are not corresponding to the bank structure.

16. The display device of claim 1, further comprising a black matrix layer disposed on the first substrate, wherein the black matrix layer comprises an opening, and the color filter layer is disposed in the opening.

17. The display device of claim 16, wherein the plurality of microlens units are not corresponding to the black matrix layer.

18. The display device of claim 1, further comprising an optical adjusting layer disposed between the light emitting unit and the light converting layer.

19. The display device of claim 1, further comprising an anti-reflection layer disposed on the second substrate.

20. The display device of claim 19, further comprising an antifouling layer disposed on the anti-reflection layer.
